(19) United States
(12) Patent Application Publication
(10) Pub. No.: US 2015/0284843 A1
(43) Pub. Date: Oct. 8, 2015

(54) COATING LAYER OF ZIRCONIUM COMPOSITE MATERIAL AND METHOD OF FORMING COATING LAYER

(71) Applicant: Hyundai Motor Company, Seoul (KR)

(72) Inventors: Seung-Chan Hong, Sungnam (KR); Seong-Jin Kim, Sungnam (KR); So-Jung Shim, Seoul (KR)

(21) Appl. No.: 14/556,108

(22) Filed: Nov. 29, 2014

(30) Foreign Application Priority Data
Apr. 7, 2014 (KR) 10-2014-41202

(51) Int. Cl. C23C 16/06; C23C 16/455; C23C 16/46; C23C 16/34

(52) U.S. Cl. CPC C23C 16/06; C23C 16/34; C23C 16/45536; C23C 16/45529; C23C 16/46

(57) ABSTRACT

Disclosed are a coating layer of a zirconium composite material which can be applied to a friction portion and the like of a power train part of a vehicle, and a method of forming the coating layer. In particular, the coating layer of a zirconium composite material includes a ZrCuAlMo layer that is an intermediate layer for close contact force and a ZrCuAlMoN layer that is a functional layer for a low friction coefficient and durability and the ZrCuAlMo layer and ZrCuAlMoN layer are sequentially laminated on a surface of a base material to reduce friction of the friction portion. Accordingly, wear resistance, durability life, and the like may be improved, close contact force with the base material may be improved, and impact resistance and the like may be enhanced.

### CROSS-REFERENCE TO RELATED APPLICATIONS

This application claims priority under 35 U.S.C. §119 to Korean Patent Application No. 10-2014-41202, filed on Apr. 7, 2014, in the Korean Intellectual Property Office, the disclosure of which is incorporated herein by reference in its entirety.

### TECHNICAL FIELD

The present invention relates to a coating layer of a zirconium composite material which can be applied to a friction portion and the like of a power train part of a vehicle, and a method of forming the coating layer. In particular, the coating layer may include an intermediate layer having substantially improved contact force and a functional layer having a low friction coefficient and improved durability.

### BACKGROUND

Mechanical parts such as engines and transmissions of a vehicle serve to transfer kinetic energy to wheels through an interlocking mechanical movement. However, between mechanical parts, substantial portion of the kinetic energy is lost and the parts are worn caused by friction that is generated during sliding movement, rotation movement, reciprocal movement, and the like.

In order to solve these problems, low friction and high durability surface treatments have been variously used to reduce friction of a friction portion at which the mechanical parts come into contact with each other to cause friction. Thus, an energy loss due to friction may be reduced, and fuel efficiency of vehicles, durability life and the like of the mechanical parts may be improved. Typically, chromium (Cr) plating, nitriding treatment, coating of nitrides such as CrN, and the like have been used, a low friction characteristic may not be obtained sufficiently and durability of the parts to which the aforementioned method is applied may be reduced.

In the related arts, a DLC (diamond like carbon) coating having greater friction characteristic and durability than CrN coating has been developed. However, when the DLC coating layer is formed by using a PVD (physical vapor deposition) method, formation efficiency of the coating layer may be reduced and cost competitiveness may also be reduced since a process time may be about 12 hours or greater due to a substantially low sputtering yield of a graphite target.

Moreover, when the DLC coating layer is formed by using a CVD (chemical vapor deposition) method, a process rate may increase as compared to the PVD method, but hardness and durability of the formed DLC coating layer may be reduced.

Due to such disadvantages in elevated residual stress of DLC itself, an intermediate layer such as Cr, CrN, and WCC may be essentially provided. However, production efficiency may be reduced due to insertion of the intermediate layer made of a different material.

As such, a coating layer which can implement production efficiency due to a higher deposition rate than those of DLC and is effective in improving low friction and wear resistance of friction portion parts is highly desired.

### SUMMARY OF THE INVENTION

The present invention provides technical solutions to reduce friction of a friction portion and the like and increase durability and the like by providing an effective coating layer with an optimum thickness.

In an exemplary embodiment, a coating layer of a zirconium composite material may include: a ZrCuAlMo layer which is an intermediate layer for increasing close contact force between the base material and a ZrCuAlMoN layer and in contact with an upper surface of a base material; and the ZrCuAlMoN layer which is a functional layer having a friction coefficient that is lower than that of the base material and in contact with an upper surface of the ZrCuAlMo layer. Particularly, the ZrCuAlMoN layer may include a mixture layer which is a concentration gradient layer formed by gradually increasing a nitrogen (N) content from one surface coming into contact with the ZrCuAlMo layer to the other surface.

In certain exemplary embodiments, the ZrCuAlMo layer may include zirconium (Zr), copper (Cu), aluminum (Al), and molybdenum (Mo), and the ZrCuAlMoN layer may include zirconium (Zr), copper (Cu), aluminum (Al), molybdenum (Mo), and nitrogen (N).

In certain exemplary embodiments, a thickness of the ZrCuAlMo layer may be greater than about 0 μm and equal to or less than about 0.5 μm. A thickness of the ZrCuAlMoN layer may be from about 0.1 to about 10 μm.

In certain exemplary embodiments, the coating layer may be a multilayered thin film coating layer having a structure where the ZrCuAlMo layer and the ZrCuAlMoN layer are repeatedly laminated. In yet certain exemplary embodiments, the ZrCuAlMo layer and ZrCuAlMoN layer of the multilayered thin film coating layer may be, independently, greater than about 0 μm and equal to or less than about 0.5 μm.

In another exemplary embodiment, provided is a method of forming a coating layer of a zirconium composite material. The method may comprise steps of: a first step of injecting an argon (Ar) gas into a coating chamber and then forming a plasma state having an argon ion (Ar⁺); a second step of heating the coating chamber to activate zirconium (Zr), copper (Cu), aluminum (Al), and molybdenum (Mo) targets and ionize thereof; a third step of depositing ionized copper (Cu), aluminum (Al), and molybdenum (Mo) ions on one surface of a base material to form a ZrCuAlMo layer; and a fourth step of gradually increasing a concentration of nitrogen gas (N₂) in the coating chamber to form a ZrCuAlMoN layer including a mixture layer. Particularly, in the mixture layer, the nitrogen content may gradually increase from an upper surface of the ZrCuAlMo layer so that the ZrCuAlMoN layer comes into contact with the upper surface of the ZrCuAlMo layer.

In certain exemplary embodiments, after the concentration of the nitrogen gas (N₂) in the coating chamber is reduced to form the ZrCuAlMo layer on the upper surface of the ZrCuAlMoN layer, forming of the ZrCuAlMoN layer on the upper surface of the formed ZrCuAlMo layer by gradually increasing the concentration of the nitrogen gas (N₂) may be repeated to form a multilayered thin film coating layer having a structure formed by repeatedly laminating the ZrCuAlMo layer and the ZrCuAlMoN layer at least two times or greater on the upper surface of the base material.

In certain exemplary embodiments, the ZrCuAlMo layer formed in the third step may include zirconium (Zr), copper (Cu), aluminum (Al), and molybdenum (Mo), and a thickness of the ZrCuAlMo layer may be greater than about 0 μm and equal to or less than about 0.5 μm. In yet certain exemplary embodiments, the ZrCuAlMoN layer formed in the fourth step includes zirconium (Zr), copper (Cu), aluminum (Al), molybdenum (Mo), and nitrogen (N), and a thickness of the ZrCuAlMoN layer is from about 0.1 to about 10 μm.

In certain exemplary embodiments, in the fourth step, the concentration of the nitrogen gas (N₂) may gradually increase when the mixture layer is formed from about 0 to about 50 vol % based on a volume of the argon gas (Ar).

In yet certain exemplary embodiments, in the fourth step, the concentration of the nitrogen gas (N₂) when the ZrCuAlMoN layer is formed may be from about 5 to about 50 vol % based on the volume of the argon gas (Ar).

As described above, according to various exemplary embodiments of the present invention, friction of a friction portion may be reduced to improve wear resistance, durability life, and the like. Further, improved close contact force with a base material may be obtained, and impact resistance and the like may be improved.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 illustrates a cross-sectional view of an exemplary coating layer of a zirconium composite material according to an exemplary embodiment of the present invention.

FIG. 2 is an exemplary graph illustrating a change in nitrogen (N) content in a ZrCuAlMo layer 20 and a ZrCuAlMoN layer 30 including a mixture layer 40 according to an exemplary embodiment of the present invention.

FIG. 3 illustrates a cross-sectional view of an exemplary multilayered thin film coating layer according to an exemplary embodiment of the present invention. Illustrated are exemplary coating layers of the zirconium composite material repeatedly laminated.

FIG. 4 schematically illustrates a cross-sectional view of an exemplary coating device according to an exemplary embodiment of the present invention.

FIG. 5 is a microscopic view after a close contact force test in Example 1 according to an exemplary embodiment of the present invention.

### DETAILED DESCRIPTION OF THE EMBODIMENTS

Terms or words used in the present specification and claims should not be interpreted as being limited to typical or dictionary meanings, but should be interpreted as having meanings and concepts which comply with the technical spirit of the present invention, based on the principle that an inventor can appropriately define the concept of the term to describe his/her own invention in the best manner.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Hereinafter, the present invention will be described in detail with reference to drawings, Tables, and the like.

The present invention relates to a coating layer of a zirconium composite material and a method of forming the coating layer. In one aspect, the present invention provides the coating layer of a zirconium composite material, which may reduce friction of a friction portion of a power train part and the like of a vehicle and improve wear resistance thereof.

In general, in order to reduce friction of the friction portion in an engine, a transmission, and the like and improve durability life and the like of those parts, a coating layer and the like are formed on a surface of the friction portion and the like.

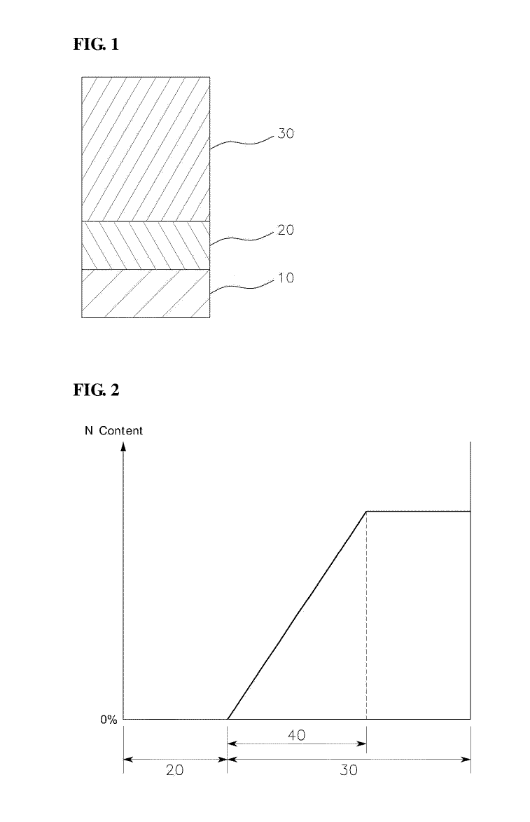

FIG. 1 is a cross-sectional view illustrating a cross-section of a coating layer of a zirconium composite material according to an exemplary embodiment of the present invention. As illustrated in FIG. 1, the coating layer may include: a ZrCuAlMo layer 20 that is in contact with an upper surface of a base material 10, which is an upper portion of a surface of the base material 10. Friction may occur at the upper portion of the surface of the base material due to contact with another adjacent material. The ZrCuAlMo layer 20 may also be an intermediate layer for increasing close contact force between the base material 10 and a ZrCuAlMoN layer 30 which is a functional layer. Particularly, the coating layer according to an exemplary embodiment of the present invention may include the ZrCuAlMoN layer 30 which is in contact with an upper surface of the ZrCuAlMo layer 20 and has a friction coefficient that is lower than that of the base material.

In certain exemplary embodiments, the ZrCuAlMoN layer 30 may include a mixture layer 40 which is a concentration gradient layer formed by gradually increasing a nitrogen (N) content from the upper surface of the ZrCuAlMo layer to a contacting area with the ZrCuAlMo layer 20. In this case, the mixture layer 40 may improve close contact force between the ZrCuAlMo layer 20 and the ZrCuAlMoN layer 30.

That is, the coating layer has a structure where the ZrCuAlMo layer 20 which is the intermediate layer for close contact force between the base material 10 and the ZrCuAlMoN layer 30. The ZrCuAlMoN layer 30 which is the functional layer may have a lower friction coefficient than that of the base material 10 or the ZrCuAlMo layer 20 and may provide durability. In certain exemplary embodiments, the ZrCuAlMo layer 20 and the ZrCuAlMoN layer 30 may be sequentially laminated on the surface of the base material, which may be the upper surface of the base material 10. In other certain exemplary embodiments, the ZrCuAlMoN layer 30 may include the mixture layer 40. The mixture layer 40 may suppress a reduction in bonding force, which may occur between the different materials by forming the concentration gradient layer.

In yet certain exemplary embodiments, the ZrCuAlMo layer 20 which is the intermediate layer may increase close contact force between the base material 10 and the functional layer. Accordingly, the base material 10 and the ZrCuAlMoN layer 30 may be adhered sufficiently. In yet certain exemplary embodiments, the ZrCuAlMo layer 20 may include zirconium (Zr), copper (Cu), aluminum (Al), molybdenum (Mo), and the like.

In certain exemplary embodiments, a thickness of the ZrCuAlMo layer 20 may be greater than about 0 μm and equal to or less than about 0.5 μm. When the thickness is greater than 0.5 μm, a total thickness of the coating layer may increase, but an effect of close contact force of the base material 10 and the ZrCuAlMoN layer 30 may not increase accordingly, and thus efficiency of the coating layer may be reduced and a manufacturing cost of the coating layer may increase.

As used herein, the ZrCuAlMoN layer 30 that is the functional layer may have high hardness and the low friction coefficient as compared to DLC (diamond like carbon) used in the related art and a high deposition rate to the base material 10. Accordingly, the ZrCuAlMoN layer 30 may effectively improve a low friction property, wear resistance, and the like of the friction portion and the like. In addition, since a coating forming rate is high, formation efficiency of the coating layer and the like may be improved. In certain exemplary embodiments, the ZrCuAlMoN layer 30 may include zirconium (Zr), copper (Cu), aluminum (Al), molybdenum (Mo), nitrogen (N), and the like.

In yet certain exemplary embodiments, the thickness of the ZrCuAlMoN layer 30 may be from about 0.1 to about 10 μm. When the thickness is less than about 0.1 μm, since the thickness of the ZrCuAlMoN layer 30 may substantially decrease, the ZrCuAlMoN layer 30 may be easily damaged by small impact, and thus the ZrCuAlMoN layer may not serve as the functional layer. When the thickness is greater than 10 μm, even though the thickness of the ZrCuAlMoN layer 30 increases, characteristics such as the friction coefficient and wear resistance may not be improved accordingly, and thus, the manufacturing cost with respect to an effect of the coating layer may increase. Accordingly, a total thickness of the ZrCuAlMo layer 20 and the ZrCuAlMoN layer 30 may be in a range of from about 0.1 to about 10.5 μm.

In certain exemplary embodiments, the coating layer of the zirconium composite material according to an exemplary embodiment of the present invention may further include the mixture layer 40 for improving close contact force between the ZrCuAlMo layer 20 and the ZrCuAlMoN layer 30. Particularly, the mixture layer 40 may be positioned between the ZrCuAlMo layer 20 and the ZrCuAlMoN layer 30 and the concentration gradient layer may be formed by gradually increasing a nitrogen (N) concentration in a direction from the ZrCuAlMo layer 20 to the ZrCuAlMoN layer 30.

In still certain exemplary embodiments, the mixture layer 40 may include zirconium (Zr), copper (Cu), aluminum (Al), molybdenum (Mo), nitrogen (N), and the like, and a thickness of the mixture layer 40 may be from about 0.1 to about 0.5 μm, or particularly of about 0.5 μm. When the thickness of the mixture layer 40 is less than about 0.1 μm, the concentration gradient may not be formed. When the thickness is greater than 0.5 μm, an effect by the concentration gradient may not increase accordingly and thus a total coating for thickness may increase as compared to the effect.

FIG. 2 is a graph showing a change in nitrogen (N) content in an exemplary ZrCuAlMo layer 20 and an exemplary ZrCuAlMoN layer 30 including an exemplary mixture layer 40 according to an exemplary embodiment of the present invention. Particularly, the mixture layer 40 may be positioned between the ZrCuAlMo layer 20 and the ZrCuAlMoN layer 30 and may be formed by, but not limited to, a concentration gradient thin film method.

In other certain exemplary embodiments, in the mixture layer 40, the concentration gradient of nitrogen (N) may be formed. The nitrogen (N) fraction of the mixture layer 40 in contact with the ZrCuAlMo layer 20 may be less than the nitrogen (N) faction of an upper surface that is in contact with the other contacting area to the ZrCuAlMoN layer 30, which is not in contact with the ZrCuAlMo layer 20.

Accordingly, since the coating layer according to the present invention includes the mixture layer that is the concentration gradient layer, attachment force between the ZrCuAlMo layer 20 and the ZrCuAlMoN layer 30 may increase. For example, the attachment force between the ZrCuAlMo layer 20 and the ZrCuAlMoN layer 30 without the mixture layer 40 may be about 20 to 30 N, but attachment force between the ZrCuAlMoN layer 30 including the mixture layer 40 and the ZrCuAlMo layer 20 may be about 40 N. That is, since the mixture layer 40 is the concentration gradient layer and minimizes a deviation between the two layers through a gradual change in nitrogen content between the ZrCuAlMo layer 20 and the ZrCuAlMoN layer 30, attachment force of the two layers may be improved.

When the ZrCuAlMoN layer 30 that is the outermost surface layer of the coating layer is worn out, physical properties of the coating layer may not be reduced immediately, due to the mixture layer 40 that is the concentration gradient layer having a small physical property deviation with the ZrCuAlMoN layer 30.

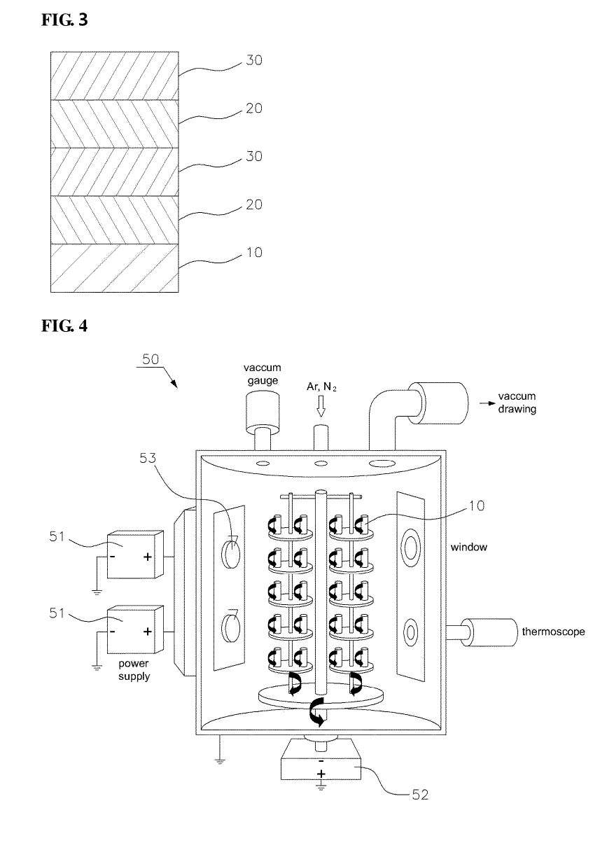

FIG. 3 is a cross-sectional view illustrating an exemplary multilayered thin film coating layer where exemplary coating layers of the zirconium composite material are repeatedly laminated. As illustrated in FIG. 3, the multilayered thin film coating layer may be a multilayered thin film coating layer having a structure where the ZrCuAlMo layer 20 and the ZrCuAlMoN layer 30 are repeatedly laminated at least two times or more on the surface of the base material 10. In certain exemplary embodiments, the coating layer may be in a form of the multilayered thin film coating layer. The multilayered thin film coating layer may have advantages in that hardness, such that wear resistance, impact resistance, and the like of the coating layer may be further improved. Further, the close contact force with the base material 10 and the like may be significantly improved as compared to a single coating layer.

In certain exemplary embodiments, a thicknesses of the ZrCuAlMo layer 20 and the ZrCuAlMoN layer 30 which are laminated to form the multilayered thin film coating layer may be independently greater than about 0 μm and equal to or less than about 0.5 μm. When the thickness of each of the ZrCuAlMo layer 20 and the ZrCuAlMoN layer 30 is greater than 0.5 μm, a cost put to form coating may increase as compared to an effect by lamination. In yet certain exemplary embodiments, the ZrCuAlMoN layer 30 may include the mixture layer 40 to improve close contact force, attachment force, and the like of the ZrCuAlMo layer 20 and the ZrCuAlMoN layer 30.

The coating layer of the zirconium composite material according to various exemplary embodiments of the present invention may be applied to the friction portion and the like, particularly to the friction portion of a power train part of a vehicle and the like, requiring the low friction coefficient, improved wear resistance and impact resistance, and the like instead of DLC (diamond like carbon) coating, chromium (Cr) plating, or the like in the related art.

Hereinafter, in another aspect, the present invention provides a method of forming a coating layer of a zirconium composite material.

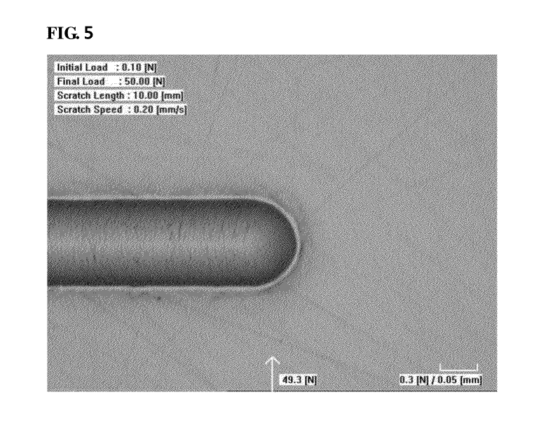

In an exemplary embodiment, the method of forming the coating layer of the zirconium composite material may be, but not limited to, a plasma sputtering method. FIG. 4 is a cross-sectional view schematically illustrating an exemplary coating device. The method of forming the coating layer include steps of: a first step of vacuumizing a coating chamber, injecting an argon (Ar) gas, and forming a plasma state having an argon ion (Ar⁺) by applying a current to induce electrons generated at a cathode and the argon (Ar) gas to collide; a second step of heating the coating chamber at about 200° C. to activate zirconium (Zr), copper (Cu), aluminum (Al), and molybdenum (Mo) targets and induce the argon ion (Ar⁺) and the zirconium (Zr), copper (Cu), aluminum (Al), and molybdenum (Mo) targets to collide and thereby ionizing thereof; a third step of depositing ionized copper (Cu), aluminum (Al), and molybdenum (Mo) ions on a surface of a base material to form a ZrCuAlMo layer; a fourth step of gradually introducing a nitrogen gas (Ns) and increasing gradually a concentration of the nitrogen gas (N₂) in the coating chamber to form a ZrCuAlMoN layer including a mixture layer that is a concentration gradient layer in which a nitrogen content is gradually increased from an upper surface of the ZrCuAlMo layer so that the ZrCuAlMoN layer comes into contact with the upper surface of the ZrCuAlMo layer.

In certain exemplary embodiments, in the first step, the current may be applied to a coating power supply 51, a bias power supply 52, and the like.

In certain exemplary embodiments, after the concentration of the nitrogen gas (N₂) in the coating chamber is reduced to form the ZrCuAlMo layer on the upper surface of the ZrCuAlMoN layer, forming of the ZrCuAlMoN layer on the upper surface of the formed ZrCuAlMo layer by gradually increasing the concentration of the nitrogen gas (N₂) may be repeated at least two times or more in order to form a multilayered thin film coating layer having a structure formed by repeatedly laminating the ZrCuAlMo layer and the ZrCuAlMoN layer on the upper surface of the base material 10. In yet certain exemplary embodiments, the thicknesses of the ZrCuAlMo layer and ZrCuAlMoN layer of the multilayered thin film coating layer may be independently greater than about 0 μm and equal to or less than about 0.5 μm.

Alternatively, after the first step and the second step, the third step and the fourth step may be repeated at least two times or more in order to form the multilayered thin film coating layer having a structure formed by repeatedly laminating the ZrCuAlMo layer and the ZrCuAlMoN layer on the surface of the base material.

In certain exemplary embodiments, in the third step, the composition of the ZrCuAlMo layer may include: zirconium (Zr), copper (Cu), aluminum (Al), molybdenum (Mo), and the like. In addition, the thickness of the ZrCuAlMo layer be greater than about 0 μm and equal to or less than about 0.5 μm.

In yet certain exemplary embodiments, in the fourth step, the composition of the ZrCuAlMoN layer may include zirconium (Zr), copper (Cu), aluminum (Al), molybdenum (Mo), nitrogen (N), and the like. Further, the thickness of the ZrCuAlMoN layer may be from about 0.1 to about 10 μm.

In certain exemplary embodiments, the mixture layer may include zirconium (Zr), copper (Cu), aluminum (Al), molybdenum (Mo), nitrogen (N), and the like. In other certain exemplary embodiments, the mixture layer may be formed, but not limited to, by a concentration gradient thin film method. The thickness of the mixture layer may be from about 0.1 to about 0.5 μm, or particularly of about 0.5 μm.

In certain exemplary embodiments, in the fourth step, the concentration of the nitrogen gas (N₂), which is gradually increased in order to form the mixture layer, may be greater than about 0 vol % and equal to or less than about 50 vol % based on a volume of the argon gas (Ar). When the concentration of the nitrogen gas (N₂) is about 0 vol %, formation of the mixture layer may be limited. When the concentration of the nitrogen gas (N₂) is greater than about 50 vol %, a gradual concentration gradient may not be formed, and thus an effect of presence of the mixture layer may be reduced.

In yet certain exemplary embodiments, in the fourth step, a flow rate of the nitrogen gas (N₂) for forming the mixture layer may be related to a volume of the coating chamber, and the flow rate of the nitrogen gas (N2) may be from about 0 to about 30 sccm. Particularly, a concentration gradient thin film-type mixture layer may be formed by gradually increasing the flow rate of the nitrogen gas (N₂) from about 0 sccm to about 30 sccm. When the flow rate of the nitrogen gas (N₂) is greater than 30 sccm, a stepwise concentration gradient of the mixture layer may not be implemented. In particular, the nitrogen gas (N₂) may be about 30 sccm. When the flow rate is not in the aforementioned range, the ZrCuAlMoN layer having sufficiently improved physical properties such as wear resistance may not be obtained.

Furthermore, in the fourth step, the concentration of the nitrogen gas (N₂) for forming the ZrCuAlMoN layer may be from about 5 to about 50 vol % based on the volume of the argon gas (Ar).

### EXAMPLE

Hereinafter, the present invention will be described in more detail through the Examples. These Examples are only for illustrating the present invention, and it will be obvious to those skilled in the art that the scope of the present invention is not interpreted to be limited by these Examples.

The friction coefficient, wear rate, close contact force, hardness, and deposition rate of the coating layer of the zirconium composite material in Examples according to exemplary embodiments of the present invention were compared to those of the Comparative Example as used in the related art.

TABLE 1

| | | | Compar- | Compar- | Compar- |
|---|---|---|---|---|---|
| Classifi- | | | ative | ative | ative |
| cation | Unit | Example 1 | Example 1 | Example 2 | Example 3 |
| Material | — | ZrCuAlMoN | Nitriding | CrN | DLC |
| Method | — | PVD | Heat | PVD | PVD |
| | | | treatment | | |
| Coating | μm | 2 | — | 2 | 2 |
| thickness | | | | | |
| Friction | — | 0.07 | 0.14 | 0.12 | 0.09 |
| coefficient | | | | | |
| Wear rate | μm/hr | 0.06 | 0.15 | 0.06 | 0.08 |
| Close contact | N | 49.3 | — | 30 | 35 |
| force | | | | | |
| Hardness | Hv | 1,600 | 650 | 1,300 | 2,300 |
| Deposition rate | μm/hr | 10 | — | 0.3 | 0.2 |

In Table 1, shown are physical properties of the Example having the coating layer of the zirconium composite material according to an exemplary embodiment of the present invention, of Comparative Example 1 in which the surface of the base material is subjected to nitriding treatment, of Comparative Example 2 having the CrN coating layer formed on the surface of the base material, and of Comparative Example 3 having the DLC coating layer formed on the surface of the base material.

In the coating methods of Example 1, Comparative Example 2, and Comparative Example 3 having the coating layer with the exception of Comparative Example 1, physical vapor deposition was performed, and the coating layers had the same coating thickness.

The aforementioned friction coefficients were obtained by measuring the friction coefficient between the coated disc-shaped rotation plate and the SUJ2 pin through the rotary friction and wear tester. Measurement was performed under the test condition of the load of about 160 N, the temperature of about 27° C., and the rotation rate of the rotation plate of about 100 RPM under the presence of oil for about 1 hour. The load was set so that the high pressure of about 1.5 GPa was applied by calculating the area and the pressure.

As a test result, the friction coefficient of Example 1 was about 0.07 which was the lowest friction coefficient value, and the friction coefficient of Example 1 was reduced by about 0.09 from that of Comparative Example 3 or by about 22%. Accordingly, since the low friction coefficient was relevant to low friction, friction of Example 1 to which the present invention was applied was the lowest.

The wear rate was obtained by measuring the wear amount between the coated disc-shaped rotation plate and the bearing steel pin through the rotary friction and wear tester. Measurement was performed under the test condition of the load of about 160 N, at a temperature of about 25° C., and the rotation rate of the rotation plate of about 100 RPM under the presence of oil for about 1 hour.

As a test result, the wear rate of Example 1 was about 0.06 μm/hr, which was reduced by about 60% from Comparative Example 1 where only nitriding treatment was performed without coating, was reduced by about 30% from Comparative Example 2 having the CrN coating layer, and was about equal to the wear rate of Comparative Example 3 having the DLC coating layer.

The close contact force is a value obtained by measuring the degree of close contact between the coating layer and the base material, and was measured through occurrence of scratches by the probe through the scratch tester at the load of about 0 to about 50 N and at a temperature of about 25° C. FIG. 5 is a microscopic view after a close contact force test of Example 1 was finished, and illustrates improved base material close contact force without stripping or breakage of the coating layer until the load reached to about 49.3 N. Accordingly, the close contact force of Example 1 was significantly elevated from that of Comparative Example because the mixture layer between the intermediate layer and the functional layer was formed by the concentration gradient thin film method to minimize a deviation of residual stresses between the coating layers.

Furthermore, the hardness of Example 1 was improved by about 1,416 Hv from the average of the Comparative Examples, and since the deposition rate was significantly elevated from that of Comparative Example 2 and Comparative Example 3, formation efficiency of the coating layer was improved.

Accordingly, the coating layer of the zirconium composite material according to various exemplary embodiments of the present invention may achieve the low friction coefficient and wear rate, high close contact force, and improved formation efficiency of the coating layer as compared to the coating layer used in the related art.

As described above, the present invention has been described in relation to exemplary embodiments of the present invention, but the embodiments are only illustration and the present invention is not limited thereto. Embodiments described may be changed or modified by those skilled in the art to which the present invention pertains without departing from the scope of the present invention, and various alterations and modifications are possible within the technical spirit of the present invention and the equivalent scope of the claims which will be described below.

What is claimed is:

1. A coating layer of a zirconium composite material, comprising:
a ZrCuAlMo layer which is an intermediate layer for close contact force; and
a ZrCuAlMoN layer which is a functional layer for a low friction coefficient and durability,
wherein the ZrCuAlMo layer and the ZrCuAlMoN layer are sequentially laminated on a surface of a base material.

2. The coating layer of the zirconium composite material of claim 1, wherein the ZrCuAlMoN layer includes a mixture layer which is a concentration gradient layer formed by gradually increasing a nitrogen (N) content from a surface coming into contact with the ZrCuAlMo layer.

3. The coating layer of the zirconium composite material of claim 1, wherein the ZrCuAlMo layer includes zirconium (Zr), copper (Cu), aluminum (Al), and molybdenum (Mo).

4. The coating layer of the zirconium composite material of claim 1, wherein a thickness of the ZrCuAlMo layer is greater than about 0 μm and equal to or less than about 0.5 μm.

5. The coating layer of the zirconium composite material of claim 1, wherein the ZrCuAlMoN layer includes zirconium (Zr), copper (Cu), aluminum (Al), molybdenum (Mo), and nitrogen (N).

6. The coating layer of the zirconium composite material of claim 1, wherein a thickness of the ZrCuAlMoN layer is from about 0.1 to about 10 μm.

7. The coating layer of the zirconium composite material of claim 2, wherein the mixture layer includes zirconium (Zr), copper (Cu), aluminum (Al), molybdenum (Mo), and nitrogen (N).

8. The coating layer of the zirconium composite material of claim 1, wherein a thickness of the mixture layer is from about 0.1 to about 0.5 μm.

9. The coating layer of the zirconium composite material of claim 1, wherein the coating layer includes a multilayered thin film coating layer having a structure where the ZrCuAlMo layer and the ZrCuAlMoN layer are repeatedly laminated on an upper surface of the base material.

10. The coating layer of the zirconium composite material of claim 9, wherein thicknesses of the repeatedly laminated ZrCuAlMo layer and ZrCuAlMoN layer are each greater than about 0 μm and equal to or less than about 0.5 μm.

11. A method of forming a coating layer of a zirconium composite material, comprising steps of:
a first step of injecting an argon (Ar) gas into a coating chamber and then forming a plasma state having an argon ion (Ar⁺);
a second step of heating the coating chamber to activate zirconium (Zr), copper (Cu), aluminum (Al), and molybdenum (Mo) targets and ionize thereof;
a third step of depositing ionized copper (Cu), aluminum (Al), and molybdenum (Mo) ions on one surface of a base material to form a ZrCuAlMo layer; and
a fourth step of gradually increasing a concentration of a nitrogen gas (N₂) in the coating chamber to form a ZrCuAlMoN layer including a mixture layer,
wherein in the mixture layer, a nitrogen content is gradually increased from an upper surface of the ZrCuAlMo layer to a contacting area with the ZrCuAlMo layer, so that the ZrCuAlMoN layer comes into contact with the upper surface of the ZrCuAlMo layer.

12. The method of claim 11, wherein after the first step and the second step, the third step and the fourth step are repeated at least two times or more in order to form a multilayered thin film coating layer having a structure formed by repeatedly laminating the ZrCuAlMo layer and the ZrCuAlMoN layer on the surface of the base material.

13. The method of claim 11, wherein the ZrCuAlMo layer includes zirconium (Zr), copper (Cu), aluminum (Al), and molybdenum (Mo), and a thickness of the ZrCuAlMo layer is greater than about 0 μm and equal to or less than about 0.5 μm.

14. The method of claim 11, wherein the mixture layer includes zirconium (Zr), copper (Cu), aluminum (Al), molybdenum (Mo), and nitrogen (N), and a thickness of the mixture layer is from about 0.1 to about 0.5 μm.

15. The method of claim 11, wherein the ZrCuAlMoN layer includes zirconium (Zr), copper (Cu), aluminum (Al), molybdenum (Mo), and nitrogen (N), and a thickness of the ZrCuAlMoN layer is from about 0.1 to about 10 μm.

16. The method of claim 11, wherein in the fourth step, the concentration of the nitrogen gas (N₂), which is gradually increased in order to form the mixture layer, is greater than about 0 vol % and equal to or less than about 50 vol % based on a volume of the argon gas (Ar).

17. The method of claim 11, wherein in the fourth step, the concentration of the nitrogen gas (N₂) for forming the ZrCuAlMoN layer is from about 5 to about 50 vol % based on a volume of the argon gas (Ar).
